(19) United States
(12) Patent Application Publication
(10) Pub. No.: US 2018/0372650 A1
(43) Pub. Date: Dec. 27, 2018

(54) OPTICAL INSPECTION SYSTEM, PROCESSING SYSTEM FOR PROCESSING OF A MATERIAL ON A FLEXIBLE SUBSTRATE, AND METHODS OF INSPECTING A FLEXIBLE SUBSTRATE

(71) Applicant: Applied Materials, Inc., Santa Clara, CA (US)

(72) Inventors: Fabio PIERALISI, Aschaffenburg (DE); Florian RIES, Westerngrund (DE)

(73) Assignee: Applied Materials, Inc., Santa Clara, CA (US)

(21) Appl. No.: 16/062,073

(22) PCT Filed: Jan. 15, 2016
(86) PCT No.: PCT/EP2016/050823

§ 371 Date: Jun. 13, 2018

(51) Int. Cl. G01N 21/89; C23C 14/54; G01N 21/896; G01N 21/84; G01N 21/86

(52) U.S. Cl. CPC G01N 21/8901; C23C 14/547; G01N 21/8914; H05K 2201/0108; G01N 21/8422; G01N 21/86; G01N 21/896

(57) ABSTRACT

According to one aspect of the present disclosure, an optical inspection system for inspecting a flexible substrate is provided. The system includes a substrate support with an at least partially convex substrate support surface configured to guide the substrate along a substrate transportation path, the substrate support being arranged on a first side of the substrate transportation path; a light source arranged on a second side of the substrate transportation path and configured to direct a light beam through a portion of the substrate which is supported on and in contact with the convex substrate support surface; and a light detector for conducting a transmission measurement of the substrate. According to a further aspect of the present disclosure, methods of inspecting a flexible substrate are provided.

### TECHNICAL FIELD

Embodiments of the present disclosure relate to an optical inspection system for inspecting a flexible substrate, to a processing system for processing of a material on a flexible substrate including an optical inspection system, as well as to methods of inspecting a flexible substrate. Embodiments of the present disclosure particularly relate to an optical inspection system for inspecting a transparent or semitransparent flexible substrate by conducting a transmission measurement of the substrate. Embodiments also relate to a processing system for processing of a material on a flexible substrate in a vacuum chamber, wherein an optical quality of the processed substrate is inspected by conducting a transmission measurement of the processed substrate.

### BACKGROUND

Substrates, e.g. flexible substrates, are regularly processed while being moved past processing equipment. Processing may comprise coating of a flexible substrate with a coating material, e.g. metal, particularly aluminum, semiconductors or dielectric materials, conducted on a substrate for the desired applications. Particularly, coating of metal, semiconductor or plastic films or foils is in high demand in the packaging industry, semiconductor industry and other industries. Systems performing this task generally include a processing drum coupled to a processing system for moving the substrate along a substrate transportation path, wherein at least a portion of the substrate is processed while the substrate is guided on the processing drum. So-called roll-to-roll coating systems allowing substrates to be coated while being moved on the guiding surface of a processing drum can provide for a high throughput.

Typically, an evaporation process, such as a thermal evaporation process, can be utilized for depositing thin layers of coating material onto the flexible substrate. Therefore, roll-to-roll deposition systems are also experiencing a strong increase in demand in the display industry and the photovoltaic (PV) industry. For example, touch panel elements, flexible displays, and flexible PV modules result in an increasing demand for depositing suitable layers in roll-to-roll coaters with low manufacturing costs. Such devices are typically manufactured with several layers of coating material, which may be produced in roll-to-roll coating apparatuses which successively utilize several deposition sources. The deposition sources may be adapted for coating the substrate with a particular coating material while the substrate is being moved toward the next deposition source. Typically, PVD (physical vapour deposition) and/or CVD (chemical vapour deposition) processes and particularly PECVD (plasma enhanced chemical vapour deposition) processes are used for coating.

In many applications, substrates, e.g. flexible substrates such as foils or inflexible substrates such as glass plates, are inspected to monitor the quality of the substrates. For example, substrates on which layers of coating material are deposited are manufactured for the display market. Since defects may occur during the coating of the substrates, an inspection of the substrates for reviewing the defects and for monitoring the quality of the substrates is reasonable.

The inspection of the substrates can, for example, be carried out by an optical inspection system. Grain structure, grain sizes, topography and surface characteristics of the coated substrates or small particles or scratches on the substrate may be reviewed using optical inspection systems.

However, optical inspection systems may have a small depth of field. For example, the depth of field of some optical inspection systems may be in the sub-100-μm range. The grain size on the substrate surface may be below the optical resolution or out of focus, making the grains invisible for the optical system. Flexible substrates are particularly thin and delicate, which increases the requirements to be fulfilled by the optical inspection system.

Therefore, there remains a need for optical inspection systems for conducting transmission measurements of a flexible substrate with which improved quality inspection of the substrate can be achieved. There is also a need for improved methods for measuring of optical properties of flexible substrates, e.g. flexible and/or (semi-)transparent substrates coated with one or more coating layers.

### SUMMARY

In light of the above, an optical inspection system for inspecting a flexible substrate as well as a processing system for processing of a material on a flexible substrate are provided. Further, methods of inspecting a flexible substrate are provided. Further aspects, benefits, and features of the present disclosure are apparent from the claims, the description, and the accompanying drawings.

According to one aspect of the present disclosure, an optical inspection system for inspecting a flexible substrate is provided. The optical inspection system includes: a substrate support with an at least partially convex substrate support surface configured to guide the substrate along a substrate transportation path, the substrate support being arranged on a first side of the substrate transportation path; a light source arranged on a second side of the substrate transportation path and configured to direct a light beam through a supported portion of the substrate which is in contact with the substrate support surface; and a light detector for conducting a transmission measurement of the substrate.

According to a further aspect of the present disclosure, a processing system for processing of a material on a flexible substrate is provided. The processing system includes: a vacuum chamber; a substrate support with an at least partially convex substrate support surface configured to guide the substrate through the vacuum chamber along a substrate transportation path, the substrate support being arranged on a first side of the substrate transportation path; a light source arranged on a second side of the substrate transportation path and configured to direct a light beam through a supported portion of the substrate which is in contact with the substrate support surface; and a light detector for conducting a transmission measurement of the substrate, wherein at least one of the light source and the light detector is arranged outside the vacuum chamber.

According to a further aspect of the present disclosure, a method of inspecting a flexible substrate is provided. The method includes: guiding the substrate along a substrate transportation path, wherein the substrate is supported on an at least partially convex substrate support surface of a substrate support arranged on a first side of the substrate; directing a light beam from a second side of the substrate through a supported portion of the substrate which is in contact with the convex substrate support surface; and detecting the light beam having passed through the substrate at least once for conducting a transmission measurement of the substrate.

Further aspects, advantages, and features of the present disclosure are apparent from the dependent claims, the description, and the accompanying drawings.

### BRIEF DESCRIPTION OF THE DRAWINGS

So that the manner in which the above recited features of the present disclosure can be understood in detail, a more particular description of the disclosure, briefly summarized above, may be had by reference to embodiments. The accompanying drawings relate to embodiments of the disclosure and are described in the following. Typical embodiments are depicted in the drawings and are detailed in the description which follows.

FIG. 1 shows a schematic sectional view of an optical inspection system according to embodiments described herein;

FIG. 2 shows a schematic sectional view of an optical inspection system according to embodiments described herein;

FIG. 3 shows a schematic sectional view of an optical inspection system according to embodiments described herein;

FIG. 4 shows a schematic sectional view of an optical inspection system according to embodiments described herein;

FIG. 5 shows a schematic sectional view of an optical inspection system according to embodiments described herein;

FIG. 6 shows a schematic sectional view of an optical inspection system according to embodiments described herein;

FIG. 7 shows a schematic sectional view of an optical inspection system according to embodiments described herein;

FIG. 8 shows a comparative example of an optical inspection system for conducting a transmission measurement of a flexible substrate;

FIG. 9 shows a schematic view of a processing system for processing of a material on a flexible substrate according to embodiments described herein;

FIG. 10 shows a flow diagram of a method according to embodiments described herein; and

FIG. 11 shows a flow diagram of a method according to embodiments described herein.

### DETAILED DESCRIPTION

Reference will now be made in detail to the various embodiments, one or more examples of which are illustrated in each figure. Each example is provided by way of explanation and is not meant as a limitation. For example, features illustrated or described as part of one embodiment can be used on or in conjunction with any other embodiment to yield yet a further embodiment. It is intended that the present disclosure includes such modifications and variations.

Within the following description of the drawings, the same reference numbers refer to the same or to similar components. Generally, only the differences with respect to the individual embodiments are described. Unless specified otherwise, the description of a part or aspect in one embodiment applies to a corresponding part or aspect in another embodiment as well.

Coated substrates such as flexible plastic films with one or more layers deposited thereon can be characterized by specified spectral reflectance and transmittance values. Properties of the coated substrates, particularly optical properties, can be measured by optical inspection systems which may comprise a light source and a light detector. Optical inspection systems may be used to detect and identify defects in or on a substrate, e.g. micro-particles such as μm-sized particles on a processed substrate. Inspection systems may be used to inspect a stationary or a moving substrate, wherein defects can be examined with improved resolution as compared to human eye inspection.

For example, a light source may be configured to generate a light beam to be directed onto the surface of a moving substrate. Optics for focusing the light beam on the substrate for detecting defects of the substrate and/or for imaging the substrate may be provided. In some implementations, the light detector may be or comprise an imaging device such as a camera imaging device that is configured to capture an image of the substrate for the inspection thereof.

Optical inspection systems for the detection of μm-range particles on substrates may have a small depth of field, e.g. a depth of field in the range of +/−20 μm. This means that the substrate under investigation should not vary the position, e.g. by fluttering, by more than +/−20 μm along the optical path of the light beam. It is particularly difficult to reliably measure optical transmission properties of a flexible, (semi-)transparent substrate during transport thereof. For example, flexible substrates may be prone to fluttering in a direction perpendicular to the substrate transportation path, in particular at portions of the substrate where the substrate is not supported on a substrate support. Further, flexible substrates are typically thin and delicate so that such substrates may flutter by more than 20 μm at unsupported positions.

As is shown in FIG. 8, a substrate 10 is carried and conveyed from a first roller 610 to a second roller 612 along a substrate transportation path T. The first roller and/or the second roller can be guide rollers. A transmission measurement device 614 is provided in a position between the first roller 610 and the second roller 612. The area between the first roller and the second roller, where the substrate 10 is not supported on a substrate support surface, may also be referred to as “free span” or “free span position”. It is indicated that the substrate may flutter at the “free span position”, so that the optical measurement may be negatively affected. For example, the inspected web portion may move out of the focus of the light beam in a direction perpendicular to the substrate transport direction. According to embodiments of optical inspection systems described herein, an improved quality inspection of flexible, (semi-)transparent substrates can be achieved.

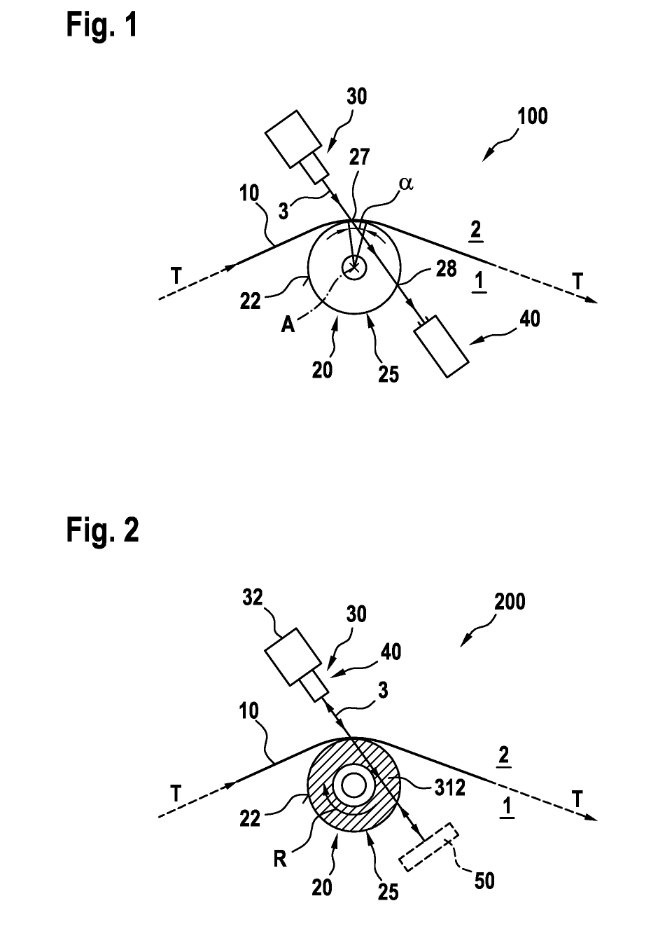

FIG. 1 shows an optical inspection system 100 for inspecting a flexible substrate 10 according to embodiments described in a schematic view. The optical inspection system 100 includes a substrate support 20 with an at least partially convex substrate support surface 22 configured to guide the substrate along a substrate transportation path T. The substrate support surface 22 of the substrate support 20 is arranged on a first side 1 of the substrate transportation path T, and a light source 30 is arranged on a second side 2 of the substrate transportation path T opposite the substrate support surface 22. The light source 30 is configured to direct a light beam 3 through the substrate 10 toward a supported portion of the substrate 10 which is supported on and in contact with the substrate support surface 22. Further, a light detector 40, e.g. an imaging device or a camera device, for detecting the light beam having passed through the substrate 10 is provided. The light detector 40 is configured to conduct a transmission measurement of the substrate. In a transmission measurement, an optical inspection information is included in the light beam having passed through the substrate, and not in a light beam reflected from a top surface of the substrate. For example, a light beam having propagated through the substrate includes information about defects such as particles or scratches of the substrate which may be relevant for quality control.

The term substrate as used herein shall particularly embrace flexible substrates such as a plastic film, a web, a foil or a strip. The term substrate shall also embrace other types of flexible substrates. A flexible substrate may be moved while being processed in a vacuum chamber. For example, the flexible substrate may be transported along a substrate transportation path T past coating devices while being coated. In some implementations, the substrate may be wound from a first roll, may be transported over the outer surface of a processing drum, e.g. a coating drum, and may be guided along the outer surfaces of further rollers. The coated flexible substrate may be wound onto a second roll.

Substrates, e.g. webs and foils, for use in embodiments described herein may be planar substrates with flat main surfaces or may be non-planar substrates with uneven surfaces. Substrates may also have both planar and non-planar surfaces.

The term “transparent” or “semitransparent” as used herein shall particularly include the capability of a structure to transmit light of the light source at least partially, particularly with relatively low scattering. For example, the substrate may transmit 10% or more, 40% or more, or 80% or more of light in the visible spectral range at normal incidence on the substrate. For example, the substrate includes polyethylene terephthalate (PET) or another transparent or semitransparent material. Even after coating with one or more coating layers, the substrate may be transparent or semitransparent. For example, the coating material may be a transparent coating material, and/or the coating layer may be a thin layer with, e.g., a thickness of less than 100 μm or less than 10 μm which transmits more than 10% or more than 40% of the incident light.

In one or more embodiments, the substrate may include, but is not limited to, a plastic sheet or web, a plastic film, paper sheet or web, or any other type of substrate which is either transparent or semitransparent and/or has one or more transparent or semitransparent layers on a surface thereof. Some substrates suitable for use in the embodiments disclosed herein may rely on inspection operation involving online, real-time feedback of inspection and defect detection data for quality control of the substrate.

As the substrate 10 is supported on the substrate support 20 during transport, the substrate support 20 is at least partially located on a first side of the substrate 10, i.e. on the first side 1 of the substrate transportation path T. For example, as is shown in FIG. 1, the substrate support surface 22 is arranged below the curved substrate transportation path T. Further, the light source 30 may be arranged on the other side as viewed from the substrate 10, i.e. on the second side 2 of the substrate transportation path T. For example, as is shown in FIG. 1, the light source 30 may be arranged above the curved substrate transportation path T. As the substrate support 20 and the light source 30 are arranged on different sides of the substrate during substrate transport, i.e. on different sides of the substrate transportation path T, the light beam may be directed from the light source 30 on the second side 2 through the substrate 10 toward the substrate support surface 22 arranged on the first side 1. As a result, the light beam may be directed from the first side 1 through a supported portion of the substrate which is supported on and in contact with the substrate support 20 to the second side 2.

The light source 30 is arranged such that the light beam can be directed through a portion of the substrate which is supported on the substrate support surface 22. As a result, fluttering or other movements of the substrate 10 in the direction of the optical axis of the light beam can be avoided. The supported portion of the substrate cannot move out of focus and the inspection quality is improved. In particular, the substrate support 20 may be fixed in place such that a distance between the light source 30 and the substrate support surface 22 remains constant during transport of the substrate. Misalignments of the substrate 10 can be kept below 100 μm, particularly below 20 μm.

In some embodiments, the light source 30 may include or be a laser device, e.g. a solid state laser, in particular a continuous wave laser which generates a continuous beam of laser light. In some implementations, the light source may include beam steering optics and/or beam shaping optics for directing the light beam toward the flexible substrate 10. For example, the light source 30 may include a focusing device configured for focusing the light beam on the substrate from the second side 2. Focusing in only one direction, e.g. in the direction of the substrate transportation path T, may be sufficient. In particular, a light beam impinging on the substrate with a predetermined width in the width direction of the substrate, e.g. 1 cm or more or 2 cm or more, may be suitable for simultaneous inspection of an extended lateral area of the substrate.

Alternatively or additionally, the light source 30 may include one or more mirrors or beam splitters for directing the light beam or a portion of the light beam toward the substrate. The light beam may interact with the substrate, e.g. with one or more defects of the substrate, and may expand on the first side 1, as the light beam moves away from the substrate. The light beam including information on the one or more defects of the substrate may be detected for inspection purposes by the light detector 40. In some embodiments, the light source 30 may include a light emitting diode LED or another source of visible or invisible radiation.

According to the embodiment shown in FIG. 1, a substrate support 20 with an at least partially convex substrate support surface 22 is provided. The substrate support surface 22 may be configured such that the flexible substrate 10 is guided on the substrate support surface 22 along the substrate transportation path T. For example, the substrate support surface 22 may be convex along the extension of the substrate transportation path T, e.g. rounded, round or circular. This has the advantage that the flexible substrate which is transported while being supported on the substrate support 20 can stay in close contact with the at least partially convex substrate support surface 22. In particular, the supported portion of the flexible substrate 10 which is inspected may adapt in shape to the convex shape of the substrate support surface.

A tight fit between the supported portion of the substrate 10 and the at least partially convex substrate support surface 22 can therefore be guaranteed also during transport of the substrate, when the substrate is moving along the substrate transportation path T. Fluttering of the substrate can be avoided particularly well when the substrate support surface 22 is at least partially cylindrical, and the substrate support 20 is configured to transport the substrate such that the substrate is in close contact with the substrate support surface over a contacting angle α of 1° or more, 2° or more, or 5° or more and/or 40° or less, particularly 20° or less with respect to a central axis of the cylindrical substrate support surface. For example, in the embodiment shown in FIG. 1, the contacting angle α between the substrate 10 and the substrate support surface 22 is more than 2° and less than 20°, particularly more than 5° and less than 10°.

In some embodiments, the substrate support 20 may include a rotatable roller 25, and the at least partially convex substrate support surface 22 may be the outer surface of the rotatable roller 25. In some implementations, the roller may be a guide roller which is provided with a drive for rotating the roller. In some implementations, the roller may be rotated by the frictional force exercised by the moving substrate. The substrate may be moved by another driving device, e.g. another guide roller. The rotatable roller 25 may be rotatable around a rotation axis A in a rotation direction R. In other embodiments, a static substrate support may be provided.

A substrate support 20 provided as a rotatable roller 25 may have a cylindrical outer surface, i.e. a convex outer surface, for supporting and guiding the flexible substrate 10 along the substrate transportation path T. The supported portion of the flexible substrate 10 which contacts the rotatable roller 25 may have a curvature corresponding to the curvature radius of the rotatable roller 25. Fluttering of the supported portion of the flexible substrate 10 is minimized in the region of the substrate, where the substrate is in close contact with the outer surface of the roller. For example, misalignment of the substrate may be kept below 100 μm, particularly below 20 μm. The rotatable roller 25 may have a radius of 7 cm or more and/or 30 cm or less.

In some embodiments, which may be combined with other embodiments disclosed herein, the light detector 40 may be arranged on the first side of the substrate, i.e. the first side 1 of the substrate transportation path T. The light beam generated by the light source 30 may propagate through the supported portion of the substrate 10 and through the substrate support 20 toward the light detector 40, as is illustrated in FIG. 1. The light detector 40 may be configured for imaging at least part of the supported portion of the substrate for detecting defects of the substrate.

In some embodiments which may be combined with other embodiments disclosed herein, the substrate support 20 is at least partially made of a transparent material for transmitting the light beam at least partially through the substrate support 20. For example, the substrate support 20 may at least partially be made of glass, quartz, silicon dioxide, optically polished quartz and/or a transparent plastic material. For example, the substrate support may be configured such that 50% or more, particularly 80% or more of the incident light are transmitted through the substrate support.

In the embodiments shown in FIG. 1, a transparent outer layer of the rotatable roller 25 is provided. The light beam 3 having propagated through the substrate 10 may enter the transparent outer layer at a first position 27 which is in contact with the substrate 10 and may exit the transparent outer layer at a second position 28 spaced apart from the first position 27, e.g. by an angle of 20° or more or 40° or more with respect to a rotation axis A of the substrate support. The light detector 40 may be arranged at a distance from the substrate support 20.

In order to avoid the rotation axis A of the rotatable roller 25 to interfere with the light beam 3, the light beam may propagate through the rotatable roller as a secant line which is parallel to a diameter line as seen in the sectional view of FIG. 1. In some implementations, the light beam 3 may hit the substrate at an angle of incidence of 2° or more, of 5° or more, particularly of 20° or more, as is illustrated in FIG. 1.

FIG. 2 shows an optical inspection system 200 according to embodiments described herein in a schematic section view. Details of the substrate support 20 and of the substrate transportation path T correspond to the optical inspection system 100 shown in FIG. 1 so that reference can be made to the above explanation which are not repeated here.

In the embodiment shown in FIG. 2, the light detector 40 is arranged on the second side 2 of the substrate transportation path T, i.e. on the same side as the light source 30. For example, the light detector 40 and the light source 30 may be arranged next to each other on the second side 2, the light detector 40 may be connected to the light source 30, and/or the light detector and the light source may be integrated in a single inspection device. It is illustrated in FIG. 2 that the light source 30 and the light detector 40 may be integrated in a housing 32 which is arranged on the second side 2 of the substrate transportation path T. In this case, the optical inspection system 200 can be provided in a particularly compact and space-saving way.

In order to make sure that the light beam 3 propagates back to the light detector 40 arranged on the second side 2, a reflective component 50 may be provided on the first side 1. The reflective component 50 may be configured for back-reflecting the light beam having propagated through the substrate 10 to the second side 2 of the substrate transportation path T.

In some implementations, the reflective component 50 may be configured for back-reflecting the light beam through the substrate 10. In particular, the reflective component 50 may be configured for back-reflecting the light beam along essentially the same light path in an opposite direction so that the light beam 3 passes a second time through the supported portion of the substrate toward the light detector 40.

In order to make sure that the light beam 3 propagates back through the substrate along essentially the same path in an opposite direction, the reflective component 50 may comprise or be configured as a retroreflector. A retroreflector is a component configured for back-reflecting a light beam essentially along the incident path. Whereas a mirror reflects an obliquely incident light beam on the opposite side of the normal to the reflection surface, a retroreflector reflects an incident beam on the same side of the normal. In particular, in a retroreflector, an incident beam may be reflected back along a vector that is essentially parallel to the vector of the incident beam (e.g. with a distance of less than 0.5 mm or less than 0.1 mm, and/or with a slight angle change of 2° or less), but opposite in direction from the beam's source. Examples of a retroreflector are a corner reflector and a cat's eye. A retroreflector may be a component that has numerous glass spheres, cubes, prisms or other devices on the surface thereof for reflecting light from the incoming beam. The retroreflector may be in alignment with the incident light beam.

When the reflective component 50 is configured as a retroreflector, the incident beam is back-reflected in the direction of the light source 30, where also the light detector 40 may be located, independent of the angle of incidence of the light beam on the reflective component 50.

In the embodiment shown in FIG. 2, the substrate support 20 is provided as a rotatable roller 25, and the at least partially convex substrate support surface 22 is the outer roller surface. An outer circumferential part of the roller is made of a transparent material so that the light beam may propagate at least partially through the substrate support 20 toward the reflective component 50. Then, the light beam may propagate back along the incident path in an opposite direction, i.e. through the transparent portion of the substrate support 20 and through the supported portion of the substrate 10 toward the light detector 40.

In some embodiments, which may be combined with other embodiments disclosed herein, a transparent outer layer 312 of the substrate support may be made of the transparent material, e.g. an outer circumferential layer of the rotatable roller with a radial thickness of 1 cm or more. In some implementations, the roller may be a hollow roller with an at least partially transparent outer roller wall. In some implementations, a ratio between the radial thickness of the transparent outer layer 312 and the radius of the roller may be 0.5 or more or 0.75 or more. In some implementations, the whole roller (apart from a roller axis) may be transparent. The number of reflections and refractions of the light beam at material interfaces may be reduced by increasing the thickness of the transparent outer layer and/or by modifying the angle of incidence of the light beam on the substrate support.

In some embodiments, a beam splitter may be provided in the housing 32 for separating the back-reflected light-beam from the generated light beam. Inspection quality may be improved, when the light beam propagates two times through the supported portion of the substrate 10.

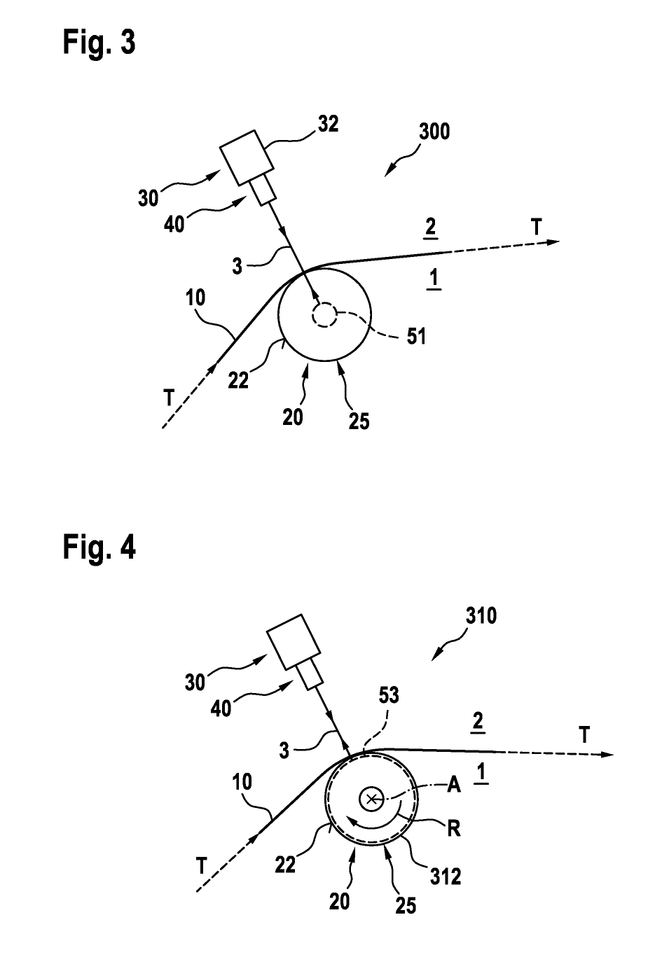

In some embodiments, the reflective component 50 may be provided as a separate or external component arranged downstream from the substrate support 20. In other embodiments, e.g. in the embodiments shown in FIGS. 3 to 5, the reflective component may be integrated in the substrate support 20. A more compact optical inspection system may be provided by integrating the reflective component in the substrate support. Further, the number of interfaces (e.g. interfaces between a transparent material and vacuum) to be passed by the light beam may be reduced by integrating the reflective component in the substrate support. Each interface to be passed by the light beam may lead to at least one further light reflection and/or light refraction and may reduce the overall intensity of the light beam 3 arriving at the light detector 40 or lead to other unfavorable effects.

Providing the reflective component 50 as a component separate from and at a distance downstream from the substrate support 20 may have the advantage that a distance between the supported portion of the substrate that is to be inspected and the reflective component 50 may be set as appropriate. For example, the light source 30 may be configured to provide a beam focus at the position of the supported portion of the substrate 10. After having interacted with a defect of the substrate, the focused beam may expand during propagation toward the reflective component 50. The expanded image of the defect may meet the reflective component 50 and be imaged by the light detector. Defect inspection quality may be improved as compared to a reflective component which is arranged closer to the supported portion of the substrate. For example, in some embodiments, a distance between the supported portion of the substrate and the reflective component may be 5 cm or more, particularly 15 cm or more, more particularly 50 cm or more.

FIG. 3 shows a schematic sectional view of an optical inspection system 300 according to embodiments described herein. Apart from the position and shape of the reflective component, the optical inspection system 300 may correspond to the optical inspection system 200 shown in FIG. 2 so that reference can be made to the above explanations which are not repeated here.

The reflective component 51 of the optical inspection system 300 may be integrated in the substrate support 20. As is shown in FIG. 3, the substrate support 20 may be provided as a rotatable roller 25, and the reflective component 51 may be provided as a reflective surface extending around the center of the rotatable roller 25 in a circumferential direction. For example, a rotation axis A of the rotatable roller 25 may be provided as the reflective component 51, e.g. as a retroreflector or as a metallic component with a reflectivity of, e.g., more than 50% or more than 90%. In particular, the reflective component 51 may be provided as a cylindrical reflective surface arranged coaxially with respect to the cylindrical substrate support surface.

In some implementations, an outer layer of the rotatable roller 25 may include a transparent material, e.g. a transparent solid material such as optically polished quartz, wherein the thickness of the outer layer may be more than 50% or more than 90% of the radius of the rotatable roller 25. In some embodiments, the substrate support 20 may be at least partially hollow, wherein an inner volume of the roller which is surrounded by a transparent cylindrical solid material layer (e.g. a glass or quartz layer) may include light-transparent gas or vacuum. An inner cylindrical surface of the rotatable roller may be provided as the reflective component 51, e.g. as retroreflector.

A reflective component 51 being provided as a reflective surface extending coaxially inside the substrate support surface 22 may provide the advantage that only a single light reflection and refraction at an interface between vacuum and a transparent layer of the substrate support 20 may be used, so that the overall light reflection can be minimized.

FIG. 4 shows a schematic view of an optical inspection system 310 according to embodiments described herein. Apart from the position and shape of the reflective component, the optical inspection system 310 may correspond to the optical inspection system 300 shown in FIG. 3 so that reference can be made to the above explanations which are not repeated here.

The reflective component 53 of the optical inspection system 310 may be integrated in the substrate support 20. As is shown in FIG. 4, the substrate support 20 may be provided as a rotatable roller 25, and the reflective component 53 may be provided as a reflective surface extending coaxially around the rotation axis A of the rotatable roller 25 in a circumferential direction.

In some embodiments, which may be combined with other embodiments disclosed herein, the reflectance of the reflective component may be 50% or more, particularly 80% or more, more particularly 90% or more.

For example, a transparent outer layer 312 of the rotatable roller 25 may be made of a transparent material, e.g. a transparent solid material, wherein the thickness of the transparent outer layer 312 may be 20% or less, particularly 10% or less of the radius of the rotatable roller 25. In some implementations, a radial thickness of the transparent outer layer 312 may by 5 cm or less or 1 cm or less. The coaxial reflective component may be arranged adjacent to the inner side of the transparent outer layer 312 of the roller. In some implementations, the roller is an at least partially hollow roller.

The reflective component 53 may be provided as a reflective surface which has a circular shape in the sectional view of FIG. 4. In some implementations, the reflective component 53 may be provided as a cylindrical retroreflector which is surrounded by the transparent outer layer 312. The light beam may propagate through the supported portion of the substrate 10 and through the transparent outer layer 312 of the rotatable roller and be reflected by the reflective component 53 to propagate essentially along the incident path in an opposite direction. The returning light beam may be inspected by the light detector 40 arranged on the second side 2 in order to determine the quality of the substrate by conducting a transmission measurement.

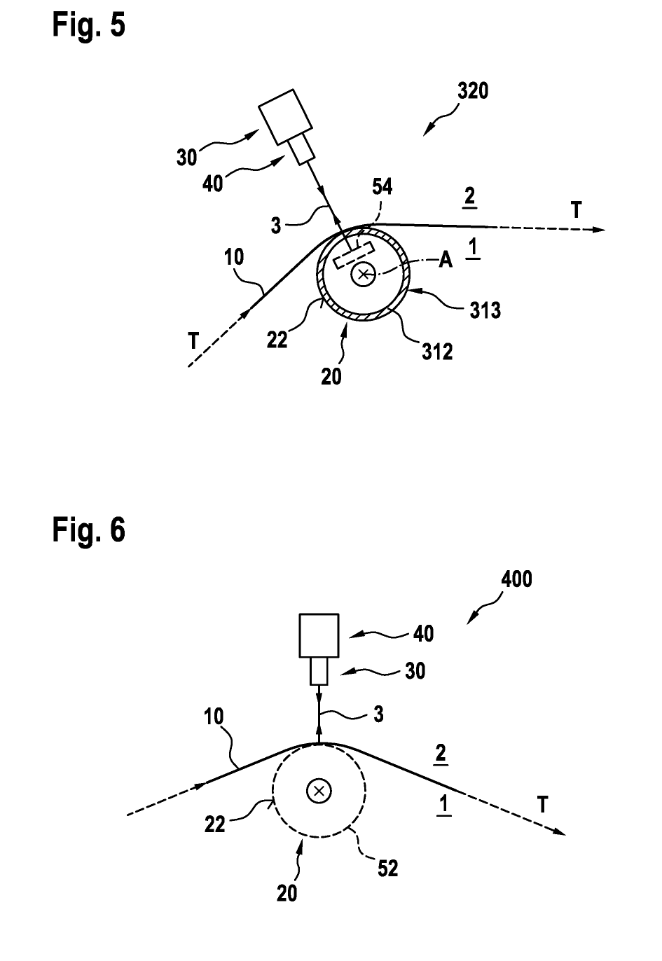

FIG. 5 shows a schematic view of an optical inspection system 320 according to embodiments described herein. Apart from the position and shape of the reflective component, the optical inspection system 320 may correspond to the optical inspection system 300 shown in FIG. 3 so that reference can be made to the above explanations which are not repeated here.

The reflective component 54 of the optical inspection system 400 may be arranged inside the substrate support 20. The reflective component 54 may have a flat reflective surface. For example, as is shown in FIG. 5, the substrate support 20 may be provided as an at least partially hollow roller 313, and the reflective component 54 may include a reflective surface, e.g. a flat reflective surface, inside the at least partially hollow roller 313.

In the embodiment shown in FIG. 5, the at least partially hollow roller 313 includes a transparent outer layer 312 made of a transparent material which may include the convex substrate support surface on which the substrate 10 is supported. In some implementations, the transparent outer layer 312 may be rotatable around the rotation axis A. The reflective component 54 may be arranged between the rotation axis A and the transparent outer layer in a stationary way. In other words, whereas the transparent outer layer 312 with the substrate support surface 22 may be rotatable, the reflective component 54 may be fixed in place inside the substrate support 20.

The reflective surface of the reflective component 54 may extend perpendicularly with respect to the light beam 3. A light beam which is incident in a normal direction with respect to the substrate support surface 22, i.e. in a radial direction of the at least partially hollow roller 313, may be back-reflected by the reflective surface in the radial direction, wherein the light beam may propagate a second time through the supported portion of the substrate 10 toward the light detector 40.

However, in some implementations, the light beam may not be perpendicular to the surface of the substrate in order to prevent an undesired back-reflection from the top surface of the substrate toward the light detector 40. This means that, in some cases, the light beam may not be perpendicular to the substrate support surface. For example, the light source 30 may be configured to direct the light beam 3 at an angle of incidence of 1° or more, particularly 2° or more, more particularly 10° or more, or even 20° or more toward the substrate support surface 22. In some implementations, an angle of incidence on the substrate of about 20° may be beneficial for optical reasons. In some implementation, an angle of incidence of less than 20° or less than 10° may be beneficial because of mechanical integration constraints.

In other words, the light beam may not be directed in a radial direction with respect to the rotatable roller 25, but at an angle thereto. The light beam 3 may perpendicularly hit the surface of the reflective component or may hit the surface of the reflective component at an angle thereto, e.g. when the reflective component is configured as a correspondingly adapted retroreflector.

In some implementations, a distance between the supported portion of the substrate 10 and the reflective component 54 may be adjustable as appropriate. This distance may affect the imaging quality of the supported portion of the substrate. For example, the distance may be adjusted in a range of 10% to 90% of the radius of the hollow roller. In some cases, a distance between the supported portion of the substrate 10 and the reflective component 54 which is larger than the radius of the roller may be appropriate. This may be possible by providing a reflective surface which extends obliquely with respect to a radial direction of the roller so that the incident light beam may laterally pass past the rotation axis A of the roller before being reflected back by the reflective component. In some cases, a distance between the supported portion of the substrate 10 and the reflective component which is larger than the diameter of the roller may be appropriate. This may be possible by arranging the reflective component outside the substrate support 20, as is shown in FIG. 2. The distance between the supported portion of the substrate 10 and the reflective component, i.e. an optical path length on the first side 1 of the substrate transportation path T, may be adjusted as appropriate.

The reflective surface of the reflective component 54 may be a metallic surface, or a retroreflector. By providing a retroreflector, a back-reflection of the light beam along the incident path (in some cases, with a slight parallel shift thereto) toward the light detector 40 can be guaranteed. Reflectance values of 80% or more, particularly 90% or more can be achieved.

FIG. 6 shows a schematic view of an optical inspection system 400 according to embodiments described herein. In the embodiment of FIG. 6, the substrate support surface 22 of the substrate support 20 itself may be configured as a reflective component 52 for back-reflecting the light beam through the substrate 10. For example, the substrate support surface 22 may be a reflective surface with a reflectance of 80% or more, particularly of 90% or more. In some implementations, the substrate support surface 22 is structured or coated as a light reflector, in particular as a laser reflector. In some implementations which may be combined with other implementations disclosed herein, the substrate support surface 22 may be configured as a retroreflector.

A substrate support surface which is provided as a retroreflector may be an uneven surface. An uneven surface may possibly damage the flexible substrate during transport of the substrate along the substrate transportation path T. Therefore, the retroreflector may be covered with, e.g. coated with, an even transparent layer, in order to provide a smooth outer surface of the substrate support 20.

In some implementations, the substrate support 20 may be provided as a rotatable roller 25, and the outer surface of the rotatable roller 25 may be the convex substrate support surface which is configured as the reflective component 52.

As is shown in FIG. 6, the light source 30 may be arranged on the second side 2 of the substrate transportation path T and configured to direct the light beam through a supported portion of the substrate 10 toward the at least partially convex substrate support surface 22 which is configured as the reflective component 52. The light beam 3 may hit the reflective component 52 at normal incidence, is back-reflected through the supported portion of the substrate, and propagates to the light detector 40 essentially along the incident path in an opposite direction. The light detector 40 is configured to detect the reflected light beam for conducting a transmission measurement of the substrate for inspecting the substrate quality.

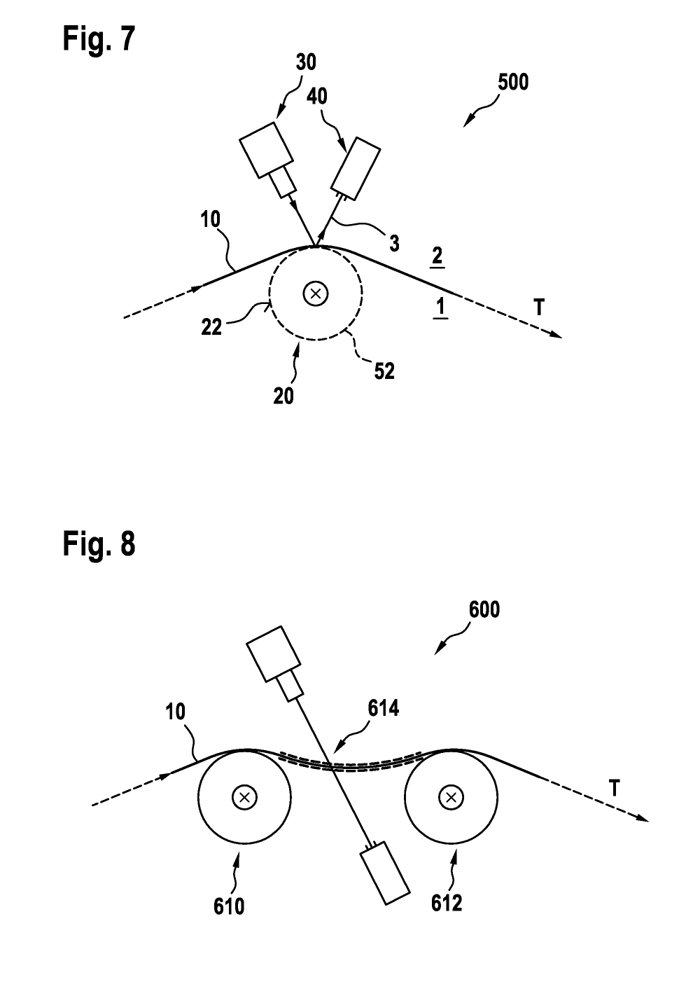

In some embodiments, e.g. in the embodiment shown in FIG. 7, the reflective component 52 may be configured as a mirror surface, e.g. as a metallic surface. The light beam having propagated through the substrate toward the first side 1, is deflected by the mirror surface back toward the second side 2 at an angle of reflection corresponding to the angle of incidence. Therefore, in the case of a non-normal incidence of the light beam on the substrate support surface 22, the light detector 40 may be arranged spaced-apart from the light source 30 on the second side 2 of the substrate transportation path T. A non-normal incidence of the light beam on the substrate may have the advantage that, depending on the thickness of the substrate, light components which are reflected from the top surface of the substrate may not enter the light detector 40. Reflected light components may be undesirable when conducting a transmission measurement of the substrate. For example, the angle of incidence of the light beam on the substrate 10 may be 1° or more and 10° or less.

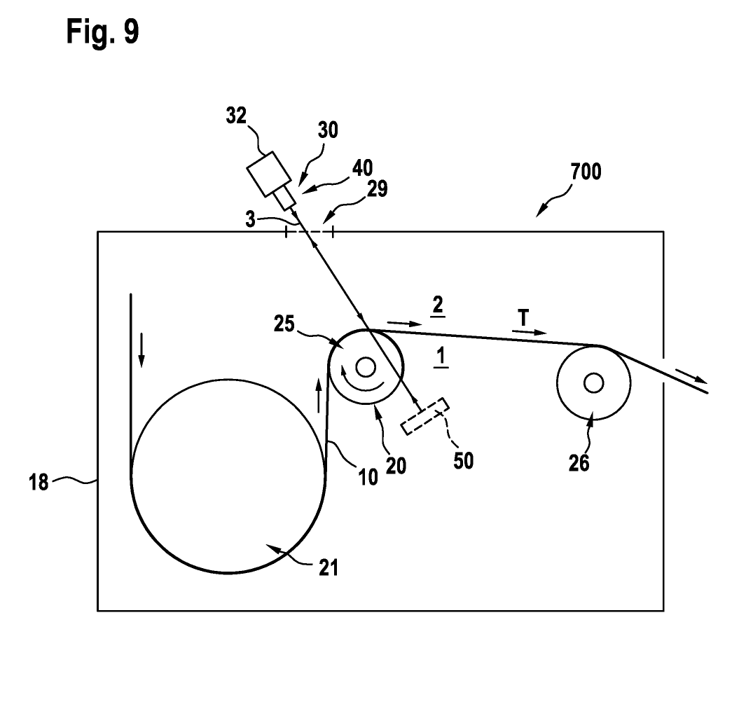

According to a further aspect, a processing system for processing of a material on a flexible substrate 10 is provided. FIG. 9 shows a schematic view of a processing system 700 according to embodiments described herein. The processing system 700 includes a vacuum chamber 18 and an optical inspection system 100, 200, 300, 310, 320, 400, 500 according to any of the above described embodiments.

The optical inspection system of the processing system 700 of FIG. 9 essentially corresponds to the optical inspection system 200 depicted in FIG. 2 so that reference can be made to the above explanations. The optical inspection system includes a substrate support 20 with an at least partially convex substrate support surface 22 configured to guide a flexible and (semi-)transparent substrate 10 through the vacuum chamber 18 along a substrate transportation path T. As is shown in FIG. 9, the substrate support 20 is arranged below the substrate 10 (on the first side 1 of the substrate transportation path T), and a light source 30 is arranged above the substrate 10 (on the second side 2 of the substrate transportation path T).

The light source 30 is configured to direct a light beam through a supported portion of the substrate 10 which is in contact with the convex substrate support surface, and a light detector 40 is provided to detect the light beam having passed through the substrate 10 at least once to conduct a transmission measurement of the substrate 10.

In the embodiments shown in FIG. 9, both the light source 30 and the light detector 40 are arranged on the same side of the substrate transportation path T, i.e. on the second side 2. In order to provide a compact inspection system which is easy to align, the light source 30 and the light detector 40 may be connected to each other. For example, the light source 30 and the light detector 40 may be integrated in a housing 32 of the inspection system. When the light beam 3 having propagated through the supported portion of the substrate is reflected via a retroreflector, the light beam will propagate back toward the light source 30 in an opposite direction. Alignment of the optical path can be minimized when the light source 30 and the light detector 40 are provided in the housing 32.

Alignment of the optical path can be further simplified when at least one of the light source 30 and the light detector 40 are arranged outside the vacuum chamber. This is because the optical path of the light beam 3 may be adjusted also during operation of the processing system, when the vacuum chamber 18 is evacuated. In particular, evacuating the vacuum chamber 18 may slightly affect the positional relationship between individual components in the optical path, e.g. the substrate support 20 or the reflective component 50.

By arranging both the light source 30 and the light detector 40 outside the vacuum chamber, beam alignment can be even further simplified. In particular, alignment of the optical inspection system is also possible during operation of the processing system, when the vacuum chamber 18 is evacuated.

Further, the light source 30 and/or the light detector 40 can also be components which are not suitable for use under vacuum conditions. Higher-quality light sources and detectors can be used which may be less costly.

In the embodiment shown in FIG. 9, both the light source 30 and the light detector 40 are arranged outside the vacuum chamber. The light beam may be coupled into the vacuum chamber 18 via an at least partially transparent window 29 or via another optical feed-through. A single transparent window may be used for coupling the light beam 3 into the vacuum chamber and for coupling the light beam having propagated through the supported portion of the substrate out of the vacuum chamber 18.

In some implementations, the substrate 10 is carried and conveyed by a coating drum 21, the rotatable roller 25 forming the substrate support 20 and at least one further roller 26. The rotatable roller 25 and/or the further roller 26 can be guide rollers. According to embodiments described herein, the transmission measurement may not be conducted at a free span position between two rollers, but at a portion of the substrate which is supported on one of the rollers. The substrate 10 may be processed, e.g. coated with one or more coating layers, while being in contact with the coating drum 21. Therefore, one or more coating devices (not shown) may be provided to be directed toward the substrate guided on the coating drum. After coating, the processed substrate may be guided toward the rotatable roller 25, wherein the transmission measurement may be conducted on a portion of the substrate which is supported on and in contact with the outer surface of the rotatable roller 25. Defects of the coating layer, e.g. μm-sized particles on or in the substrate may be detected and a quality of the coating layers may be measured.

In some embodiments, also a reflection measurement may be conducted on the substrate. The reflection measurement may be conducted on a portion of the substrate which is supported on and in contact with a substrate support surface of a substrate support, in order to improve the imaging quality.

The light beam 3 may have a width that is smaller than the width of the substrate 10 when propagating through the substrate. For example, the width of the light beam 3 may be 1 cm or more and 10 cm or less, and the width of the substrate may be 30 cm or more. Therefore, the optical inspection system may be adapted for inspecting the quality of only a part of the substrate in a width direction of the substrate (which is the direction perpendicular to the paper plane of FIG. 9). In some implementations, the light source 30 may be arranged such that a fault-prone portion of the substrate is irradiated by the light beam 3, e.g. a lateral edge portions of the substrate 10.

Two or more optical inspection systems may be provided such that two or more fault-prone portions of the substrate in a width direction of the substrate may be simultaneously inspected by conducting transmission measurements. For example, the processing system 700 may include a first light source integrated with a first light detector for inspecting a right edge region of the substrate, and a second light source integrated with a second light detector for inspecting of a left edge region of the substrate. In some embodiments, three, four, five, six, or more optical inspection systems may be provided for simultaneously conducting transmission measurements of the substrate. In some embodiments, the full width of a flexible substrate having a width of 10 cm or more may be inspected by a number of adjacently arranged optical inspection systems. In some embodiments, all light sources and/or all light detectors may be arranged outside the vacuum chamber 18. A single window or several windows may be included in a wall of the vacuum chamber for incoupling and outcoupling of the light beams.

In some embodiments, which may be combined with other embodiments disclosed herein, the optical inspection system 100, 200, 300, 310, 320, 400, 500 may include a solid state laser reflection scanner (SSLR scanner). A light detector with a line scan camera may image the returned light beam. Images of the detected defects of the substrate may be provided.

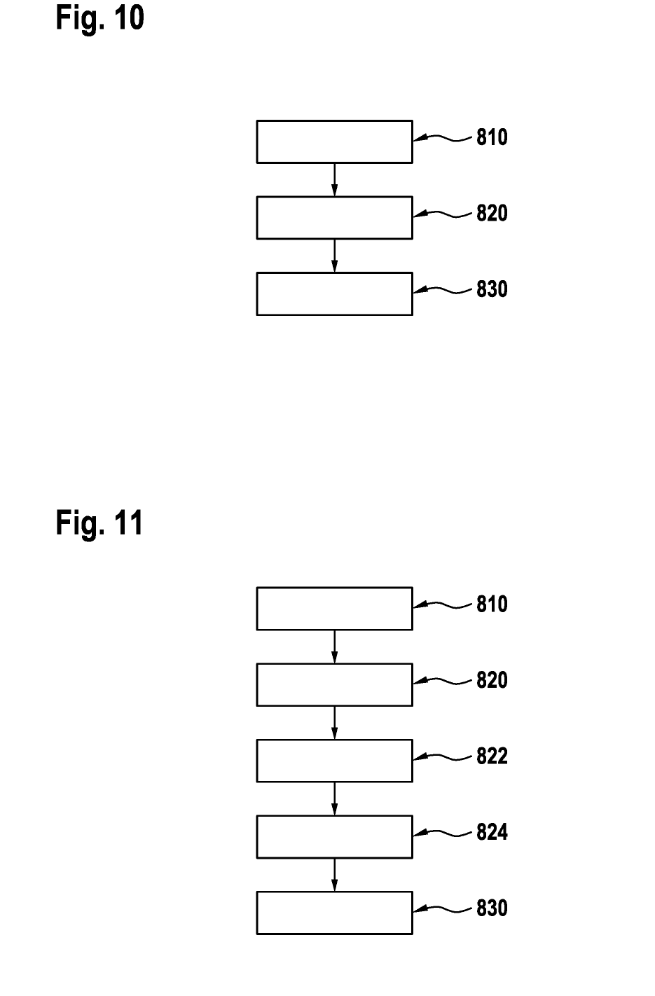

According to a further aspect, a method of inspecting a flexible substrate is provided. FIG. 10 shows a flow diagram illustrating a method of inspecting a flexible, (semi-)transparent substrate, e.g. a web, foil, or flexible sheet.

In box 810, the flexible substrate 10 is transported along a substrate transportation path T, wherein the substrate 10 is supported on an at least partially convex substrate support surface 22 arranged on a first side 1 of the substrate, e.g. below the substrate. The convex substrate support surface may be the outer surface of a rotatable roller configured for transporting the flexible substrate.

In box 820, a light beam, e.g. a laser beam, is directed from a second side 2 of the substrate through a supported portion of the substrate which is in contact with the substrate support surface 22 toward the first side 1 of the substrate.

In box 830, the light beam having passed through the substrate at least once is detected and a transmission measurement of the substrate is conducted. Defects of the substrate, e.g. scratches or small particles on or in the substrate, can be detected.

In some implementations, the substrate is a coated flexible web, e.g. a foil which has been coated with one or more coating layers, wherein the quality of the coating layers is inspected.

Detecting the light beam may include imaging of the supported portion of the substrate for detecting defects of the substrate, particularly for detecting particles on or in a coating layer of the substrate.

FIG. 11 shows a flow diagram illustrating a method of inspecting a flexible, (semi-)transparent substrate 10 which includes the following additional actions: In box 824, the light beam having propagated through the supported portion of the substrate is reflected back to the second side 2 of the substrate, where the light beam is detected by a light detector. In some implementations, the light beam is reflected back through the supported portion of the substrate. The light beam may propagate a second time through a defect to be detected which may improve the detection quality.

In some embodiments which may be combined with other embodiments described herein, the light beam is propagated through a transparent portion of the substrate support 20, as is depicted by box 822. In particular, the substrate support surface may be a transparent surface which allows at least part of the light beam to enter the substrate support and/or to propagate partially or entirely through the substrate support.

In some implementations, the light beam may be detected on the first side 1 of the substrate after having propagated through the substrate support. In other implementations, the light beam may be back-reflected at least partially through the substrate support as well as through the supported portion of the substrate. The light beam having propagated through the supported portion of the substrate twice may then be detected on the second side 2 of the substrate.

The light beam may be back-reflected by a reflective component, e.g. by a retroreflector. The reflective component may be integrated in the substrate support. The reflective component may be arranged inside the substrate support. The reflective component may be a stationary component arranged behind the substrate support surface as seen from the substrate. The substrate support surface may be the outer surface of a transparent outer layer of the substrate support. The reflective component may be provided as a reflective surface which extends around a rotations axis of a rotatable roller. For example, the reflective component may be rotatable together with a rotatable roller. The reflective component may be provided as a component separate from and downstream from the substrate support. A distance between the supported portion of the substrate and the reflective component may be adjusted.

The term “arranged on the second side 2 of the substrate transportation path T” may also have the meaning of “arranged in the optical path of the light beam upstream from the supported portion of the substrate”. The term “arranged on the first side 1 of the substrate transportation path T” may also have the meaning of “arranged in the optical path of the light beam downstream from the supported portion of the substrate”.

While the foregoing is directed to embodiments of the disclosure, other and further embodiments of the disclosure may be devised without departing from the basic scope thereof, and the scope thereof is determined by the claims that follow.

1. An optical inspection system for inspecting a flexible substrate, comprising:
a substrate support with an at least partially convex substrate support surface configured to guide the substrate along a substrate transportation path, the substrate support being arranged on a first side of the substrate transportation path;
a light source arranged on a second side of the substrate transportation path and configured to direct a light beam through a supported portion of the substrate which is in contact with the substrate support surface; and
a light detector for conducting a transmission measurement of the substrate.

2. The optical inspection system of claim 1, wherein the substrate support comprises a rotatable roller and the at least partially convex substrate support surface is an outer surface of the rotatable roller.

3. The optical inspection system of claim 1, wherein the substrate support is at least partially made of a transparent material for transmitting the light beam at least partially through the substrate support.

4. The optical inspection system of claim 16, wherein an outer 20 circumferential layer of the rotatable roller is made of the transparent material.

5. The optical inspection system of claim 1, further comprising a reflective component arranged on the first side of the substrate transportation path for back-reflecting the light beam to the second side of the substrate transportation path.

6. The optical inspection system of claim 5, wherein the reflective component comprises a retroreflector.

7. The optical inspection system of claim 5, wherein the reflective component is integrated in the substrate support.

8. The optical inspection system of claim 1, wherein the light detector is arranged on the second side of the substrate transportation path.

9. The optical inspection system of claim 8, wherein the light detector and the light source are connected to each other.

10. The optical inspection system of claim 1, wherein the substrate support surface is configured as a reflective component for back-reflecting the light beam through the substrate.

11. A processing system for processing of a material on a flexible substrate, comprising:
a vacuum chamber; and
an optical inspection system for inspecting the substrate, comprising:
a substrate support with an at least partially convex substrate support surface configured to guide the substrate through the vacuum chamber along a substrate transportation path, the substrate support being arranged on a first side of the substrate transportation path;
a light source arranged on a second side of the substrate transportation path and configured to direct a light beam through a supported portion of the substrate which is in contact with the substrate support surface; and
a light detector for conducting a transmission measurement of the substrate,
wherein at least one of the light source and the light detector is arranged outside the vacuum chamber.

12. A method of inspecting a flexible substrate, comprising:
guiding the substrate along a substrate transportation path, wherein the substrate is supported on an at least partially convex substrate support surface of a substrate support arranged on a first side of the substrate;
directing a light beam from a second side of the substrate to the first side of the substrate through a supported portion of the substrate which is in contact with the substrate support surface; and
detecting the light beam having passed through the substrate at least once for conducting a transmission measurement of the substrate.

13. The method of claim 12, wherein the light beam propagates through a transparent portion of the substrate support.

14. The method of claim 12, wherein the light beam is reflected and 20 propagates back through the substrate.

15. The method of claim 12, wherein detecting the light beam comprises imaging of the supported portion of the substrate for detecting defects of the substrate.

16. The optical inspection system of claim 2, wherein the substrate support is at least partially made of a transparent material for transmitting the light beam at least partially through the substrate support.

17. The optical inspection system of claim 5, wherein the reflective component is configured for back-reflecting the light beam through the substrate.

18. The optical inspection system of claim 9, wherein the light detector and the light source are integrated in a housing.

19. The optical inspection system of claim 13, wherein the substrate support surface is structured or coated as a light reflector.

20. The method of claim 15, wherein particles on or in a coating layer of the substrate are detected.
